(19) United States
(12) Patent Application Publication
(10) Pub. No.: US 2013/0069126 A1
(43) Pub. Date: Mar. 21, 2013

(54) GERMANIUM-BASED NMOS DEVICE AND METHOD FOR FABRICATING THE SAME

(71) Applicants: Ru Huang, Beijing (CN); Zhiqiang Li, Beijing (CN); Xia An, Beijing (CN); Yue Guo, Beijing (CN); Xing Zhang, Beijing (CN)

(72) Inventors: Ru Huang, Beijing (CN); Zhiqiang Li, Beijing (CN); Xia An, Beijing (CN); Yue Guo, Beijing (CN); Xing Zhang, Beijing (CN)

(73) Assignee: PEKING UNIVERSITY, Beijing (CN)

(21) Appl. No.: 13/519,857

(22) PCT Filed: Feb. 21, 2012
(86) PCT No.: PCT/CN12/71393

§ 371 Date: Jun. 28, 2012

(30) Foreign Application Priority Data
Jun. 23, 2011 (CN) 201110171004.2

(51) Int. Cl. H01L 29/78; H01L 21/283

(52) U.S. Cl. 257/288; 438/586; 257/E29.255; 257/E21.19

(57) ABSTRACT

An embodiment of the invention provides a germanium-based NMOS device and a method for fabricating the same, which relates to fabrication process technology of an ultra-large-scale-integrated (ULSI) circuit. The germanium-based NMOS device has two dielectric layer interposed between a metal source/drain and a substrate. The bottom dielectric layer includes a dielectric material having a high pinning coefficient S such as hafnium oxide, silicon nitride, hafnium silicon oxide or the like, and the top dielectric layer includes a dielectric material having a low conduction band offset ΔE_{C} such as titanium oxide, gallium oxide, strontium titanium oxide or the like. According to the method, Fermi level pinning effect can be alleviated, electron barrier height can be lowered, and thus performance of the germanium-based Schottky NMOS device can be improved. Compared with a conventional single dielectric layer such as aluminum oxide (Al₂O₃), Schottky barrier height can be lowered while low source/drain resistances can be maintained, and thus performance of the device can be significantly improved.

### CROSS-REFERENCES TO RELATED APPLICATION

The present application claims priority to Chinese Patent Application No. 201110171004.2, filed on Jun. 23, 2011, which is incorporated herein by reference in its entirety as if set forth herein.

### FIELD OF THE INVENTION

An embodiment of the invention relates to fabrication process technology of ultra-large-scale-integrated (ULSI) circuit, and particularly, to a germanium-based NMOS device and a method for fabricating the same.

### BACKGROUND OF THE INVENTION

With the shrink of CMOS device, a traditional silicon-based MOS device has encountered many challenges, in which mobility degradation has become one of key limiting factors to further enhance the device performance. Compared with silicon, germanium has higher and more symmetrical low field carrier mobility. Furthermore, the fabrication process of germanium device is compatible with conventional CMOS process. Thus, the germanium-based device has become one of research hotspots.

Germanium-based Schottky MOS transistor is a very promising device structure. The main difference between germanium-based Schottky MOS transistor and conventional MOS transistor is that, the traditional highly-doped source/drain is replaced by metal or metal germanide source/drain. Therefore, the contact between the source/drain and the channel changes to Schottky junction of metal and semiconductor from a PN junction. As such, not only the problems of low solid solubility and rapid diffusion of impurities in the germanium material are avoided, but also a low resistivity can be ensured and an abrupt source/drain junction can be obtained. However, there still exists some problems in the germanium-based Schottky MOS transistor, and one problem lies that, the Fermi level is pinned in the vicinity of a valence band due to a large number of interface states. This issue results in a high electron Schottky barrier and seriously restricts the performance of germanium-based Schottky NMOS transistor. There are generally two sources for these interface states. One is the metal induced gap states (MIGS) due to the incomplete attenuation of an electron wave function of metal (or metal germanide) in germanium. The other comes from the dangling bonds existing on the surface of germanium, and these unsaturated dangling bonds also result in interface states.

### SUMMARY OF THE INVENTION

An object of the invention is to provide a germanium-based NMOS device capable of reducing Fermi level pinning effect and modulating the Schottky barrier height, and a method for fabricating the same.

In the germanium-based NMOS device according to the invention, a dielectric layer is interposed between the metal source/drain and the substrate, and thereby the metal or metal germanide can be prevented from generating metal induced gap states in the germanium forbidden band. And thus, the object of reducing the Fermi level pinning effect and modulating the Schottky barrier height can be achieved. In order to effectively inhibit the Fermi level pinning effect, the dielectric layer is required to have a high pinning coefficient and a small conduction band offset. However, a dielectric material which can meet the two requirements simultaneously is rare. Hence, in order to meet the requirements, the present invention proposes a dielectric layer with a bilayer structure as following: a bottom dielectric layer uses a dielectric material having a high pinning coefficient (S>0.55), such as silicon nitride (Si₃N₄), hafnium oxide (HfO₂), hafnium silicon oxide (HfSiO₄) or the like; and a top dielectric layer uses a dielectric material having a low conduction band offset (ΔE_{C}<1.0 eV), such as titanium oxide (TiO₂), gallium oxide (Ga₂O₃), strontium titanium oxide (SrTiO₃) or the like. By depositing the two dielectric layers between the source/drain and the substrate, electron barrier heights of the source/drain can be lowered, and the performance of germanium-based Schottky NMOS device can be improved.

A method for fabricating a germanium-based Schottky NMOS device according to the invention is briefly described as follows, which include the following steps:

1-1) fabricating an MOS structure over a germanium-based substrate;

1-2) depositing two dielectric layers in source/drain regions, particularly, a bottom dielectric layer that has a high pinning coefficient S, S>0.55, is deposited over the substrate, a top dielectric layer that has a low conduction band offset ΔE_{C}, ΔE_{C}<1.0 eV is deposited over the bottom dielectric layer;

1-3) sputtering a metal film with low work function, and performing an etch process to form the metal source/drain; and

1-4) forming a contact hole and a metal wiring.

The step 1-1) includes:

2-1) fabricating an isolation region over the substrate;

2-2) depositing a gate dielectric layer and a gate;

2-3) forming a gate structure; and

2-4) forming a sidewall structure.

In the step 1-1), the germanium-based substrate includes a bulk germanium substrate, a germanium-on-insulator (GOI) substrate, an epitaxy germanium substrate or the like.

In the step 1-2), the bottom dielectric layer includes a dielectric material having a high pinning coefficient S such as silicon nitride (Si₃N₄), hafnium oxide (HfO₂), hafnium silicon oxide (HfSiO₄) or the like, and the top dielectric layer includes a dielectric material having a low conduction band offset ΔE_{C} such as titanium oxide (TiO₂), gallium oxide (Ga₂O₃), strontium titanium oxide (SrTiO₃) or the like.

In the step 1-3), the metal film is an aluminium film or other metal film having a low work function.

Compared with the prior art, the present invention has the following beneficial effects.

By interposing two thin dielectric layers between the metal source/drain and the substrate, the Schottky barrier height between the source/drain and the channel formed through a contact can be effectively adjusted, an on/off ratio of the device is improved, and a sub-threshold slope is reduced. On one hand, as the bottom dielectric layer has a large pinning coefficient S, the Fermi level pinning effect can be inhibited so that a height of the Schottky barrier is varied as the work function of the metal varies. On the other hand, since the top dielectric layer has a small conduction band offset ΔEC, the electron wave function of the metal can be further blocked from introducing MIGS interface states into the semiconductor forbidden gap, and a small tunnelling resistance is ensured.

In order to effectively inhibit the Fermi level pinning effect, generally the bottom dielectric layer is required to have a pinning coefficient S, S>0.55, for example, a dielectric material having a high pinning coefficient S, such as silicon nitride (Si₃N₄), hafnium oxide (HfO₂), hafnium silicon oxide (HfSiO₄) or the like. Also, the top dielectric layer is required to have a conduction band offset ΔE_{C}, ΔE_{C}<1.0 eV, for example, a dielectric material having a low conduction band offset ΔE_{C}, such as titanium oxide (TiO₂), gallium oxide (Ga₂O₃), strontium titanium oxide (SrTiO₃) or the like. According to the method, the Fermi level pinning effect can be alleviated, the electron barrier height can be lowered, and thus performance of the germanium-based Schottky NMOS device can be improved. Compared with a conventional single dielectric layer such as aluminium oxide (Al₂O₃) or the like, the Schottky barrier height can be lowered while low source/drain resistances can be maintained, and thus the performance of device can be substantially improved.

### BRIEF DESCRIPTION OF THE DRAWINGS

FIG. 1(a)-1(j) are views showing a flow for fabricating a germanium-based Schottky NMOS device according to an embodiment of the invention.

In the drawings, 1—a germanium substrate, 2—a P-well region, 3—an isolation region, 4—a gate dielectric layer, 5—a metal gate, 6—a sidewall, 7—a bottom dielectric layer, 8—a top dielectric layer, 9—metal source/drain, 10—a metal wiring layer.

### DETAILED DESCRIPTION OF THE EMBODIMENTS

A detailed description of the invention will be described with reference to accompany drawings and detailed embodiments.

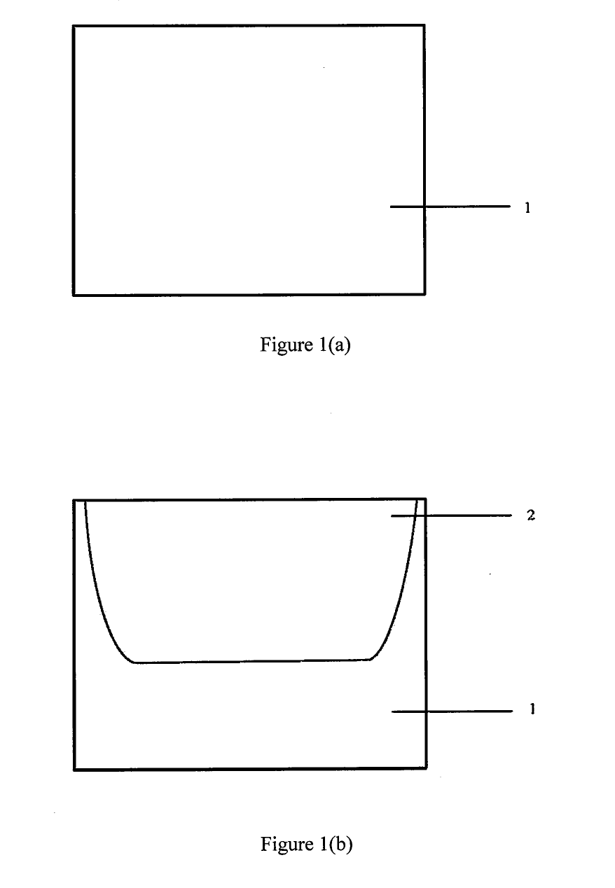

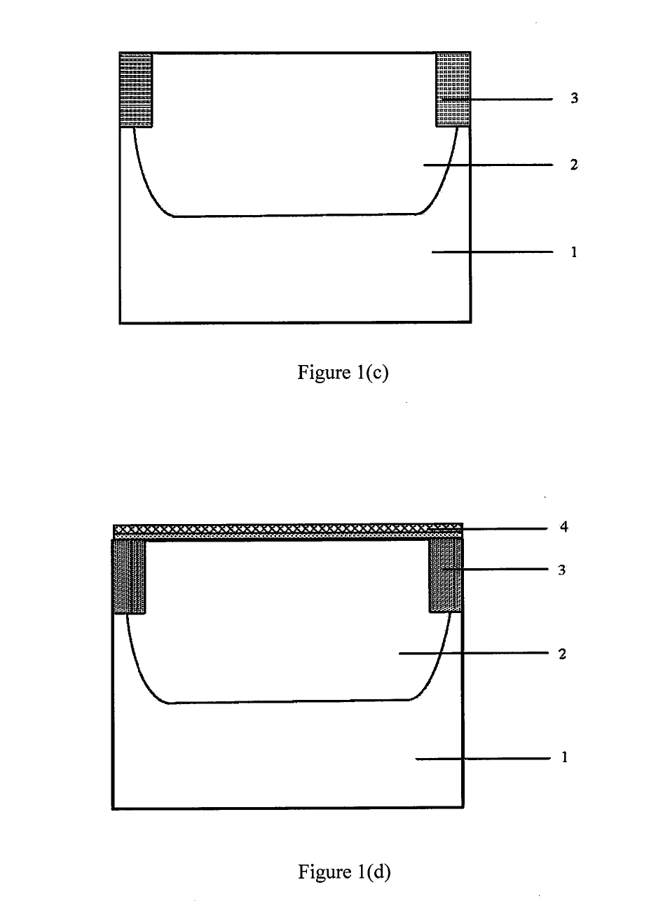

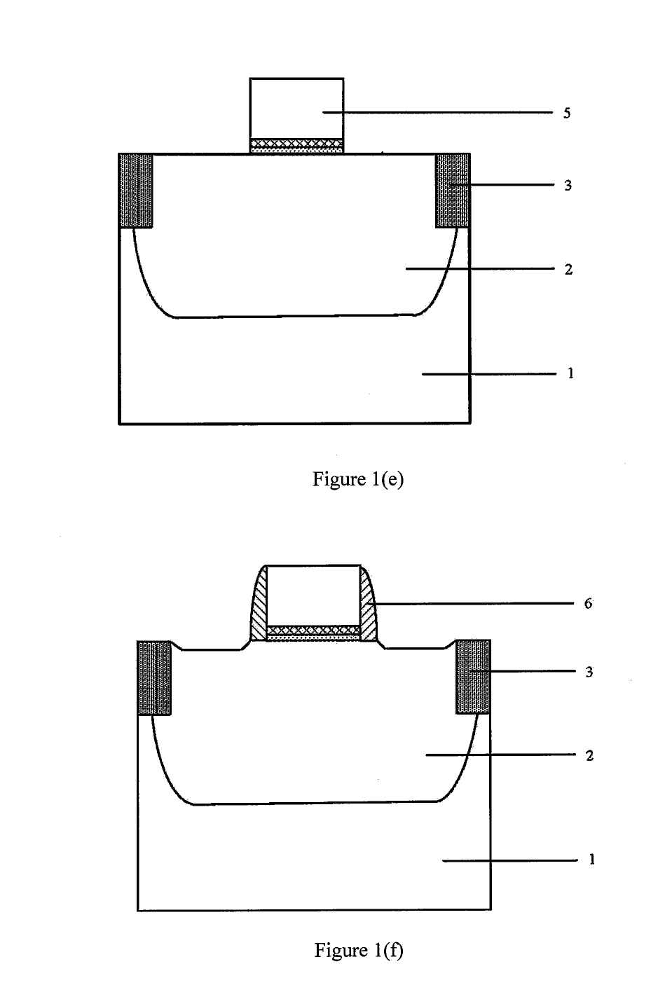

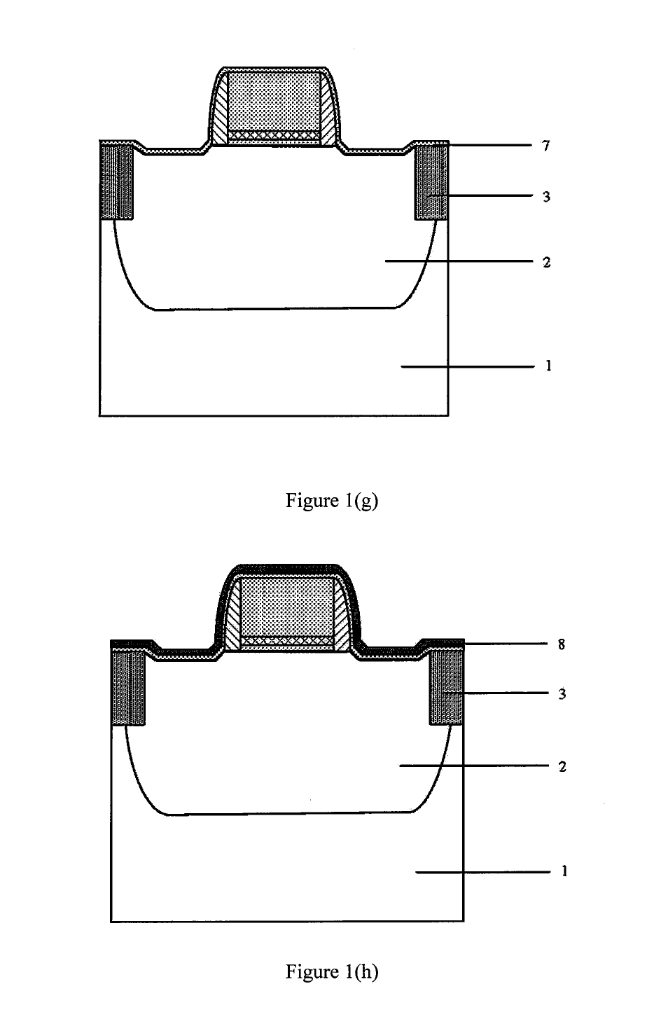

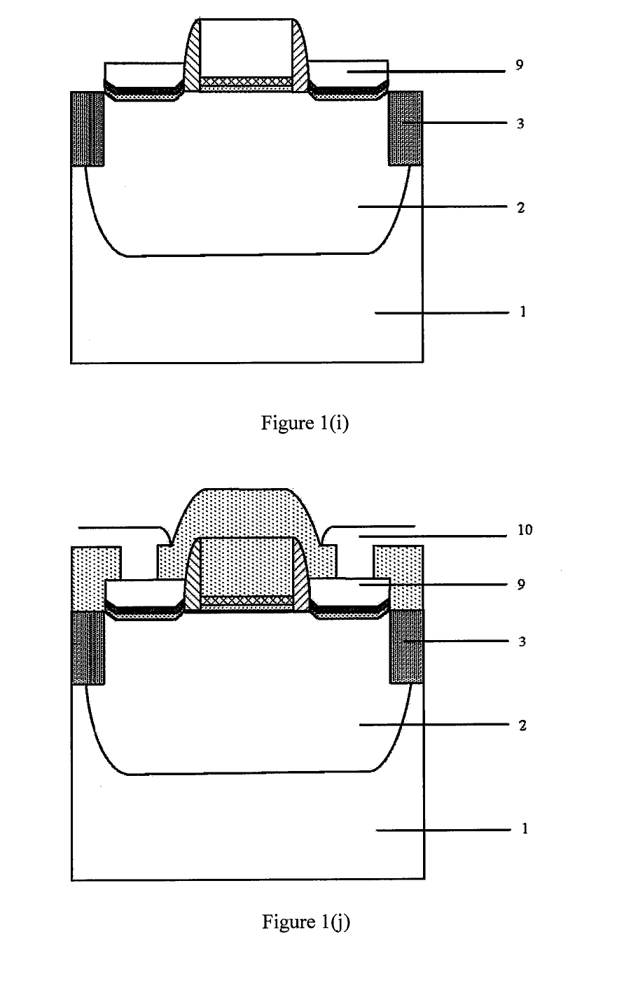

FIG. 1 shows a flow of a method for fabricating a germanium-based Schottky NMOS device according to a preferable embodiment. The method for fabricating the germanium-based Schottky NMOS device according to the embodiment of the invention includes the following steps.

Step 1: A germanium-based substrate is provided. As shown in FIG. 1(a), an N-type semiconductor germanium substrate 1 is provided, wherein, a bulk germanium substrate, a germanium-on-insulator (GOI) substrate, an epitaxy germanium substrate or the like may be used as the semiconductor germanium substrate 1.

Step 2: A P-well region is fabricated. A silicon oxide layer and a silicon nitride layer are deposited over the semiconductor germanium substrate 1. A P-type well is defined by photolithograph process and the silicon nitride layer of the P-type well is removed by a reactive-ion etch process. Then, P-type impurities such as boron are ion-implanted and driven by annealing to fabricate a P-well region 2. Finally, a mask layer used in the implantation is removed as shown in FIG. 1(b).

Step 3: A trench-isolation is implemented. For an isolation region 3 shown in FIG. 1(c), a silicon oxide layer and a nitride oxide layer are deposited over the semiconductor germanium substrate 1. Then, a trench is formed by performing a photolithography process and a reactive ion etching process on the silicon nitride layer and the silicon oxide layer and the semiconductor germanium substrate 1. Subsequently, a silicon oxide layer is deposited to fill the trench for isolation by using a chemical vapor deposition (CVD) method. Finally, a chemical mechanical polishing technology (CMP) is used to polish the resultant surface, so as to implement the isolation between devices. The device isolation is not limited to shallow trench isolation, and may also uses other technologies such as the field oxygen isolation technology.

Step 4: A gate dielectric layer is formed over an active region. The gate dielectric layer may use material such as high-K dielectric, germanium oxide, germanium nitride or the like. Before deposition of the gate dielectric layer, generally a surface passivation is required to be performed by using PH₃, NH₃, F plasma and the like, or an interface layer such as silicon (Si), aluminum nitride (AlN), yttrium oxide (Y₂O₃) or the like is deposited. In a preferable embodiment of the present invention, a thin yttrium oxide (Y₂O₃) layer is firstly fabricated over the semiconductor germanium substrate 1 as the interface layer. Then, a gate dielectric layer 4 made of hafnium oxide (HfO₂) is formed by using an atomic layer deposition (ALD) method, as shown in FIG. 1(d).

Step 5: A gate is formed over the gate dielectric layer 4. A polysilicon gate, a metal gate, a FUSI gate, an all germanide gate or the like can be used as the gate. In an embodiment, titanium nitride is deposited to form a metal gate, and then a gate structure is formed by performing a photolithography process and an etching process.

Step 6: sidewalls are fabricated on both sides of the gate. SiO₂ or Si₃N₄ may be deposited and etched to form the sidewalls, or Si₃N₄ and SiO₂ may be subsequently deposited to form the sidewalls with bilayer structure. As shown in FIG. 1(f), in the embodiment, sidewall structures 6 is formed on both sides of the gate by depositing SiO₂ and performing a dry etching process.

Step 7: A bottom dielectric layer is deposited in the source/drain regions. A dielectric material for this layer is required to have a Fermi level pinning coefficient S, wherein S>0.55. For example, silicon nitride (Si₃N₄), hafnium oxide (HfO₂), hafnium silicon oxide (HfSiO₄) or the like may be used. In a preferable embodiment, silicon nitride (Si₃N₄) is used. This layer with a thickness of 0.5-2 nm can be formed in a manner of ALD deposition, as shown in FIG. 1 (g).

Step 8: A top dielectric layer is deposited over the source/drain regions. A dielectric material for this layer is required to have a conduction band offset ΔE_{C}, wherein ΔE_{C}<1.0 eV, for example, titanium dioxide (TiO₂), gallium oxide (Ga₂O₃), strontium titanium oxide (SrTiO₃) or the like may be used. In a preferable embodiment, titanium dioxide (TiO₂) is used. This layer with a thickness of 0.5-4 nm can be formed in a manner of ALD deposition as well, as shown in FIG. 1(h).

Step 9: metal source/drain are fabricated. A metal film of low work function, such as aluminum (Al), titanium (Ti), yttrium (Y) or the like, is deposited over the semiconductor germanium substrate 1 by using a physical vapor deposition, such as evaporation or sputtering. In a preferable embodiment, aluminum which has thickness between 100 nm-1 μm is used. The metal source/drains are obtained by performing a photolithography process and an etching process, as shown in FIG. 1(i).

Step 10: A contact hole and a metal wiring are formed. Firstly, an oxidation layer of silicon oxide is deposited by CVD process. A position of the hole is defined by performing a photolithography process and the oxidation layer of silicon oxide is etched to form the contact hole. Then, a metal layer such as Al, Al—Ti or the like is sputtered. Further, a pattern of the wiring is defined by performing a photolithography process and an etching process to form the metal wiring. Finally, a metallization process is performed so as to obtain a metal wiring layer 10, as shown in FIG. 1(j).

A germanium-based NMOS device and a fabrication method thereof are provided by the embodiment of the invention. The method not only can lower the electron barrier height at the source/drain of the germanium-based NMOS device, raise the on/off current ratio of the germanium-based Schottky device and improve the performance of the germanium-based Schottky NMOS device, but also fabrication process according to the method is compatible with the silicon CMOS technology, so as to maintain an advantage of simple process. Compared with the prior art, the performance of the germanium-based Schottky NMOS device can be effectively enhanced by the device and the fabrication method thereof described herein.

A fabrication method of a germanium-based Schottky device is provided by embodiments of the invention through the above-described preferable embodiment. However, it should be understand by those skilled in the art that, the above-mentioned embodiment is a preferable embodiment of the invention. The device structure according to the invention may be modified or changed without departing from the spirit of the invention. For example, a lifted or recessed source/drain structure may be applied for the source/drain. Also, other new structures such as a double gate, a FinFET, an Ω gate, a triple gate, an all-around gate or the like may be used. The fabrication method is not limited to the content disclosed by the embodiment. Any equivalent change and modification in light of the claims of the invention are all within a range of the invention.

What is claimed is:

1. A germanium-based NMOS device, wherein, two dielectric layers are interposed between a metal source/drain and a substrate, wherein a bottom dielectric layer that has a high pinning coefficient S, S>0.55, is deposited over the substrate, a top dielectric layer that has a low conduction band offset ΔE_{C}, ΔE_{C}<1.0 eV, is deposited over the bottom dielectric layer, and the metal source/drain is deposited over the top dielectric layer.

2. The germanium-based NMOS device according to claim 1, wherein, the bottom dielectric layer comprises silicon nitride, hafnium oxide or hafnium silicon oxide.

3. The germanium-based NMOS device according to claim 1, wherein, the top dielectric layer comprises titanium oxide, gallium oxide or strontium titanium oxide.

4. The germanium-based NMOS device according to claim 1, wherein, a thickness of the bottom dielectric layer is 0.5-2 nm.

5. The germanium-based NMOS device according to claim 1, wherein, a thickness of the top dielectric layer is 0.5-4 nm.

6. A method for fabricating a germanium-based Schottky NMOS device, comprising:
1-1) fabricating an MOS structure over a germanium-based substrate;
1-2) depositing two dielectric layers in source/drain regions, wherein, a bottom dielectric layer that has a high pinning coefficient S, S>0.55, is deposited over the substrate, and a top dielectric layer that has a low conduction band offset ΔE_{C}, ΔE_{C}<1.0 eV, is deposited over the bottom dielectric layer;
1-3) sputtering a metal film having a low work function, and performing an etching process to form a metal source/drain; and
1-4) forming a contact hole and a metal wiring.

7. The method according to claim 6, wherein, the step 1-1) comprises:
2-1) fabricating an isolation region over the substrate;
2-2) depositing a gate dielectric layer and a gate;
2-3) forming a gate structure; and
2-4) forming a sidewall structure.

8. The method according to claim 6, wherein, the germanium-based substrate in the step 1-1) comprises a bulk germanium substrate, a germanium-on-insulator (GOI) substrate or an epitaxy germanium substrate.

9. The method according to claim 6, wherein, in the step 1-2), the bottom dielectric layer comprises a dielectric material having a high pinning coefficient S, such as silicon nitride, hafnium oxide, hafnium silicon oxide or the like, and the top dielectric layer comprises a dielectric material having a low conduction band offset ΔE_{C}, such as titanium oxide, gallium oxide, strontium titanium oxide or the like.

10. The method according to claim 6, wherein, the metal film in the step 1-3) is an aluminum film or other metal film having a low work function.
